(19) United States
(12) Patent Application Publication
(10) Pub. No.: US 2026/0304717 A1
(43) Pub. Date: Oct. 1, 2026

(54) INVERTER DEVICE

(71) Applicant: LS ELECTRIC CO., LTD., Anyang-Si, Gyeonggi-do (KR)

(72) Inventors: Young Hoon SONG, Anyang-si, Gyeonggi-do (KR); Young Pyong KIM, Anyang-si, Gyeonggi-do (KR)

(21) Appl. No.: 19/475,525

(22) PCT Filed: Mar. 11, 2024
(86) PCT No.: PCT/KR2024/003114

§ 371 Date: Oct. 15, 2025

(30) Foreign Application Priority Data
May 11, 2023 (KR) 10-2023-0061111

(51) Int. Cl. H05K 7/20; H02M 1/32; H02M 7/00

(52) U.S. Cl. CPC H05K 7/20936; H02M 1/327; H02M 7/003

(57) ABSTRACT

An inverter device is disclosed. The inverter device, according to one aspect of the present disclosure, comprises: a power conversion module which converts one of direct current power and alternating current power to the other; a cooling module which is coupled to the power conversion module, so as to receive heat generated therefrom; and a cover member which accommodates the power conversion module and is coupled to the cooling module to exchange heat therewith, wherein the cooling module is in direct contact with a portion of the power conversion module to exchange heat therewith, and the cover member accommodates an other portion of the power conversion module to receive heat generated by the other portion thereof, and may be arranged to be in direct contact with the cooling module.

### CROSS-REFERENCE TO RELATED APPLICATIONS

This application is the National Stage filing under 35 U.S.C. 371 of International Application No. PCT/KR2024/003114, filed on Mar. 11, 2024, which claims the benefit of earlier filing date and right of priority to Korean Application No. 10-2023-0061111, filed on May 11, 2023, the contents of which are all hereby incorporated by reference herein in their entirety.

### FIELD

The present disclosure relates to an inverter device, and more particularly, to an inverter device having a structure capable of effectively cooling generated heat.

### BACKGROUND

An inverter refers to a device for converting a direct current (DC) into an alternating current (AC). The inverter is generally configured to include a rectifier and an inverter module. The rectifier is electrically connected to an external power source to receive an AC current and convert the AC current into a DC current. The inverter module receives the converted DC current, converts it into an AC current, and delivers the converted AC current to an external load.

To perform the above-described operation, the inverter includes various types of electrical components. For example, the inverter may include a semiconductor element such as an insulated gate bipolar transistor (IGBT) configured to convert the converted DC into an AC. The semiconductor element performs a switching operation to convert the DC into the AC.

In general, a significant amount of heat is generated as the semiconductor element operates. If the generated heat is not dissipated in a timely manner, the semiconductor element or various electrical components provided in the inverter, including the semiconductor element, may be damaged. In such a case, reliable operation of the semiconductor element or the inverter may not be ensured. Furthermore, the possibility of explosion of the semiconductor element or the inverter due to overheating cannot be ruled out.

Therefore, in general, the inverter essentially requires a configuration for dissipating the generated heat.

Korean Patent Laid-Open Publication No. 10-2013-0089329 discloses an inverter cooling device. Specifically, it discloses an inverter cooling device configured to dissipate heat generated from an IGBT module by variously forming a flow path of cooling water flowing through a cooling housing.

However, the inverter cooling device disclosed in the prior document is disposed to be stacked with the IGBT and is configured to be in direct contact with the IGBT. That is, the inverter cooling device according to the prior document inevitably leads to an increase in thickness.

Korean Patent Laid-Open Publication No. 10-2015-0025755 discloses an inverter cooling device. Specifically, the publication discloses an inverter cooling device capable of adjusting an air flow rate by separating a flow path according to the amount of heat generated by an electrical element disposed therein.

However, the inverter cooling device disclosed in the prior document requires a separate movable configuration to change the flow path of air flowing inside. That is, the prior document does not provide a solution for effectively cooling the inverter cooling device without an additional member.

Korean Patent Laid-Open Publication No. 10-2013-0089329 (2013 Aug. 12.)

Korean Patent Laid-Open Publication No. 10-2015-0025755 (2015 Mar. 11.)

### SUMMARY

The present disclosure has been made in view of the above problems, and an object of the present disclosure is to provide an inverter device having a structure capable of improving cooling efficiency.

Another object of the present disclosure is to provide an inverter device having a structure capable of cooling a plurality of configurations.

Yet another object of the present disclosure is to provide an inverter device having a structure capable of preventing unintended heat exchange between a plurality of configurations.

Still another object of the present disclosure is to provide an inverter device having a structure in which each of the plurality of configurations may be modularized.

The problems of the present disclosure are not limited to those mentioned above, and other problems not mentioned will be clearly understood by those of ordinary skill in the art from the following description.

According to an aspect of the present disclosure, there is provided an inverter device including: a power conversion module configured to convert one of a direct current (DC) power and an alternating current (AC) power into the other; a cooling module configured to be coupled to the power conversion module and to receive heat generated therefrom; and a cover configured to accommodate the power conversion module and to be coupled to the cooling module to exchange heat therewith, wherein the cooling module is configured to be in direct contact with a part of configurations of the power conversion module to exchange heat therewith, and wherein the cover is disposed to accommodate another part of the configurations of the power conversion module to receive heat generated therefrom and to be in direct contact with the cooling module.

In this case, there may be provided the inverter device in which the power conversion module includes: a substrate configured to form an outer shape thereof and to be coupled to the cooling module and the cover; and a capacitor configured to be coupled to and electrically connected with the substrate, wherein the cover includes: a capacitor cover configured to be coupled to the substrate, to at least partially accommodate the capacitor, and to be in contact with the cooling module.

In addition, there may be provided the inverter device in which the capacitor is coupled through the substrate, wherein the capacitor extends in one direction, one portion in an extending direction of the capacitor is positioned at one side of the substrate, and another portion in the extending direction of the capacitor is positioned at the other side of the substrate, and wherein the capacitor cover is positioned at the other side of the substrate to accommodate another portion of the capacitor.

In this case, there may be provided the inverter device in which a length of the one portion of the capacitor is configured to be shorter than a length of another portion of the capacitor.

In addition, there may be provided the inverter device in which the cooling module includes: a cooling body configured to be coupled to the power conversion module and the cover, respectively, to receive heat generated from the power conversion module; and a cooling channel configured to be disposed inside the cooling body and to be fluidly connected to an outside, and to allow a cooling medium receiving the heat to flow therethrough, wherein the capacitor cover is coupled to one surface of the cooling body.

In this case, there may be provided the inverter device in which the cooling module includes: a cooling communicator configured to be coupled to the cooling body, fluidly connected to the cooling channel, and partially exposed to the outside, and wherein the capacitor cover is coupled to one of sides of the cooling body on which the cooling communicator is not provided.

In addition, there may be provided the inverter device in which the power conversion module includes: a substrate configured to form an outer shape thereof and to be coupled to the cooling module and the cover; and a reactor configured to be electrically connected to the substrate, wherein the cover includes: a reactor cover configured to be coupled to the cooling module and to accommodate the reactor.

In this case, there may be provided the inverter device in which the cooling module includes: a cooling body configured to be coupled to the power conversion module and the cover, respectively, to receive heat generated from the power conversion module, and wherein the reactor cover is disposed to face the substrate with the cooling body interposed therebetween.

In addition, there may be provided the inverter device in which the cooling body includes: a first cooling surface configured to be coupled to the substrate; and a second cooling surface configured to be spaced apart from the first cooling surface to face the first cooling surface, and to be coupled to the reactor cover.

In this case, there may be provided the inverter device in which the power conversion module includes: a substrate configured to form an outer shape thereof and to be coupled to the cooling module and the cover, and to have an opening formed therethrough; and an insulated gate bipolar transistor (IGBT) configured to be electrically connected to the substrate and to be disposed adjacent to the opening, wherein the cooling module is disposed to be at least partially exposed through the opening and in contact with the IGBT.

In addition, there may be provided the inverter device in which the cooling module includes: a cooling body configured to be coupled to the power conversion module and the cover, respectively, to receive heat generated from the power conversion module, and a cooling channel configured to be disposed inside the cooling body and to be fluidly connected to an outside, and to allow a cooling medium receiving the heat to flow therethrough, wherein the cooling channel includes: a first cooling channel positioned to be biased toward one side in a height direction of the cooling body.

In this case, there may be provided the inverter device in which the cooling channel includes: a second cooling channel positioned to be biased toward the other side in a height direction of the cooling body and configured to communicate with the first cooling channel, wherein the cooling module includes: a cooling communicator configured to communicate with either the first cooling channel or the second cooling channel and to form an inflow path and an outflow path of the cooling medium.

In addition, there may be provided the inverter device in which the power conversion module includes: a substrate configured to form an outer shape thereof and to be coupled to the cooling module and the cover; and a capacitor configured to be coupled to and electrically connected to the substrate, wherein the cooling channel includes: a second cooling channel positioned to be biased toward one side in a longitudinal direction of the cooling body to be adjacent to the capacitor and configured to communicate with the first cooling channel.

According to the above configuration, the inverter device according to an embodiment of the present disclosure may improve cooling efficiency.

The power conversion module includes an IGBT, a capacitor, and a reactor. The IGBT, capacitor, and reactor generate heat as the inverter device operates.

The IGBT is coupled to and electrically connected with the substrate. A cooling module is also coupled to the substrate. An opening is formed through the substrate, and the cooling module is at least partially exposed above the substrate through the opening. The IGBT may be in contact with the cooling module through the opening. That is, heat generated from the IGBT may be transferred to the cooling module in the form of conduction.

The capacitor is coupled to and electrically connected with the substrate. The substrate is coupled to a capacitor cover. The capacitor cover at least partially accommodates the capacitor, and an inner surface of the capacitor cover is configured to be in contact with the capacitor. Heat generated from the capacitor may be transferred to the capacitor cover.

The capacitor cover is coupled to the cooling module. Heat transferred to the capacitor cover may be delivered to the cooling module. That is, heat generated from the capacitor may be transferred to both the capacitor cover and the cooling module in the form of conduction.

The reactor is electrically connected to the substrate. The reactor is accommodated in a reactor cover. The reactor cover accommodates the reactor, and an inner surface of the reactor cover is configured to be in contact with the reactor. Heat generated from the reactor may be transferred to the reactor cover.

The reactor cover is coupled to the cooling module. Heat transferred to the reactor cover may be delivered to the cooling module. That is, heat generated from the reactor may also be transferred to both the reactor cover and the cooling module in the form of conduction.

Accordingly, heat generated from each of the IGBT, capacitor, and reactor may be transferred to the cooling module through different paths. Thus, the cooling efficiency of each configuration of the inverter device may be improved.

In addition, according to the above configuration, the inverter device according to an embodiment of the present disclosure may cool a plurality of configurations.

The IGBT, capacitor, and reactor are each coupled to or electrically connected to the substrate. In this case, the IGBT, capacitor, and reactor are spaced apart from each other and configured to be capable of exchanging heat with the cooling module at different positions.

Specifically, the IGBT may be in direct contact with the cooling module to exchange heat therewith. The capacitor and the reactor may exchange heat with the cooling module via the capacitor cover and the reactor cover, respectively.

Accordingly, the plurality of configurations provided in the inverter device, particularly in the power conversion module, may be cooled simultaneously or concurrently.

Also, according to the above configuration, the inverter device according to an embodiment of the present disclosure may prevent unintended heat exchange between a plurality of components.

As described above, the IGBT, capacitor, and reactor, which are the main sources of heat, are disposed to be spaced apart from one another. In addition, the heat generated from the IGBT, the capacitor, and the reactor is configured to be transferred to the cooling module along different paths.

Accordingly, unintended heat exchange between the IGBT, the capacitor, and the reactor may be prevented. As a result, the cooling efficiency of the IGBT, the capacitor, and the reactor may be improved.

Also, according to the above configuration, the inverter device according to an embodiment of the present disclosure may be configured such that each of the plurality of configurations is modularized.

As described above, the IGBT is directly coupled to the substrate. The capacitor is at least partially accommodated in the capacitor cover, and the capacitor is coupled to the substrate together with the capacitor cover. The reactor is accommodated in the reactor cover, and is coupled to the cooling module by the reactor cover.

The cooling module includes a cooling body that is coupled to the IGBT, the capacitor cover, and the reactor cover from different directions. A cooling channel through which a cooling medium flows is formed inside the cooling body, and the cooling channel is fluidly connected to an external fluid source or a fluid discharge through a cooling communicator.

That is, the capacitor, which are the main sources of heat, may be modularized with the capacitor cover. Likewise, the reactor may be modularized with the reactor cover. Furthermore, the cooling module may also be modularized by including the cooling body and the cooling communicator.

Accordingly, each configuration provided in the inverter device may be modularized.

Advantageous effects of the present disclosure are not limited to the above-described effects and should be understood to include all effects that can be inferred from the configuration of the disclosure described in the detailed description or claims of the present disclosure.

### BRIEF DESCRIPTION OF THE DRAWINGS

FIG. 1 is a perspective view illustrating an inverter device according to an embodiment of the present disclosure.

FIG. 2 is a front view illustrating the inverter device of FIG. 1.

FIG. 3 is a rear view illustrating the inverter device of FIG. 1.

FIG. 4 is a plan view illustrating the inverter device of FIG. 1.

FIG. 5 is an exploded perspective view illustrating the inverter device of FIG. 1.

FIG. 6 is a perspective view illustrating a power conversion module, a cooling module, and a cover provided in the inverter device of FIG. 1.

FIG. 7 is a right side view illustrating the power conversion module, the cooling module, and the cover of FIG. 6.

FIG. 8 is a cross-sectional perspective view taken along line A-A of FIG. 6, illustrating the power conversion module, the cooling module, and the cover.

FIG. 9 is a cross-sectional perspective view taken along line B-B of FIG. 6, illustrating the power conversion module, the cooling module, and the cover.

FIG. 10 is an exploded perspective view illustrating the power conversion module, the cooling module, and the cover of FIG. 6.

FIG. 11 is a perspective view illustrating a cooling module provided in the inverter device of FIG. 1.

FIGS. 12 to 14 are cross-sectional views illustrating the cooling module of FIG. 11.

FIG. 15 is a horizontal cross-sectional view illustrating a water flow formed inside the inverter device of FIG. 1.

FIG. 16 is a side cross-sectional view illustrating a heat transfer path formed inside the inverter device of FIG. 1.

### DETAILED DESCRIPTION

Hereinafter, embodiments of the present disclosure will be described in detail with reference to the accompanying drawings so that those skilled in the art can readily implement them. The present disclosure may be implemented in various different forms and is not limited to the embodiments described herein. For clarity of explanation, parts irrelevant to the description are omitted in the drawings, and the same or similar components are denoted by the same reference numerals throughout the entire specification.

The words and terms used in this specification and the claims should not be interpreted as being limited to their ordinary or dictionary meanings, but should be construed in accordance with the technical spirit of the present disclosure, based on the principle that the inventor is entitled to define terms and concepts in order to best describe their disclosure.

Therefore, the embodiments described in this specification and the configurations illustrated in the drawings merely correspond to a preferred embodiment of the present disclosure and do not represent the entirety of the technical spirit of the present disclosure. Accordingly, various equivalents and modifications capable of replacing such configurations may exist as of the filing date of the present disclosure.

In the following description, in order to clarify the features of the present disclosure, some configurations may be omitted.

The term “fluid communication” used in the following description refers to a state in which one or more members are connected so as to allow fluid flow between them. In an embodiment, the fluid communication may be established by members such as conduits, pipes, or tubes. In the following description, the term “fluid communication” may be used to mean that one or more members are “fluidly connected” to each other.

The term “communication” used in the following description refers to a state in which one or more components are connected to allow fluid communication with each other. In one embodiment, such communication may be formed by components such as conduits, pipes, or tubing. In the following description, the term “communication” may be used interchangeably with the expression “fluidly connected”.

The term “fluid” as used in the following description refers to any form of material that can flow under an external force and may undergo deformation in shape or volume. In one embodiment, the fluid may be a liquid such as water or a gas such as air.

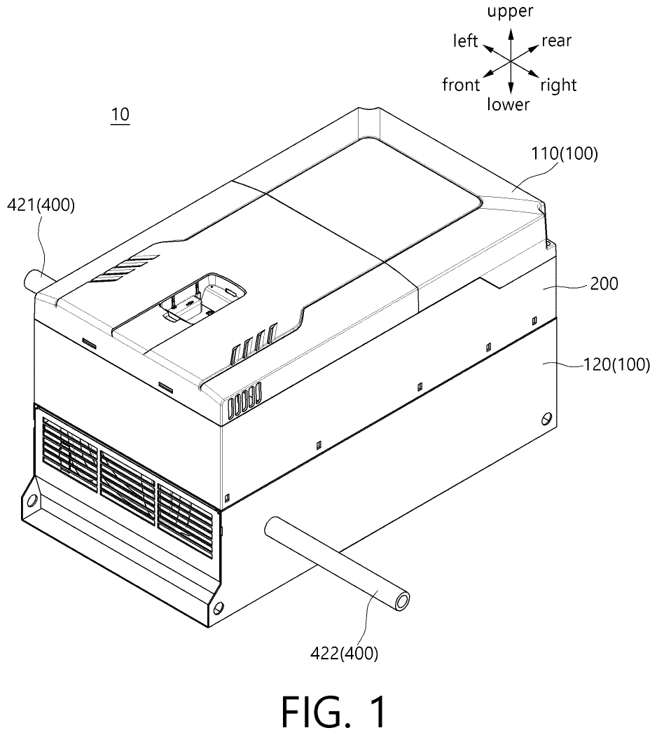

The terms “upper side,” “lower side,” “left side,” “right side,” “front side,” and “rear side” used in the following description are to be understood with reference to the coordinate system illustrated in FIG. 1.

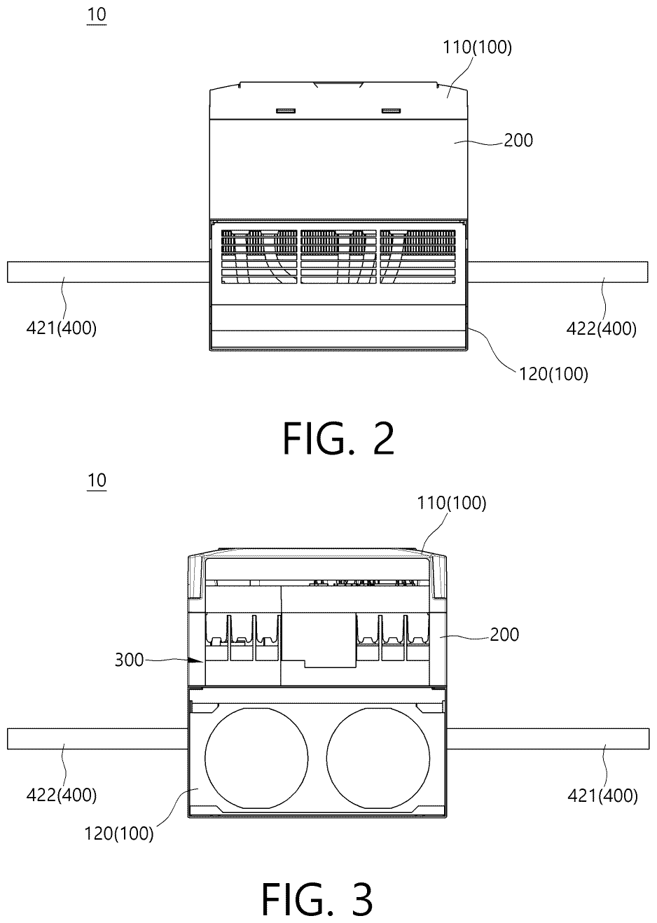

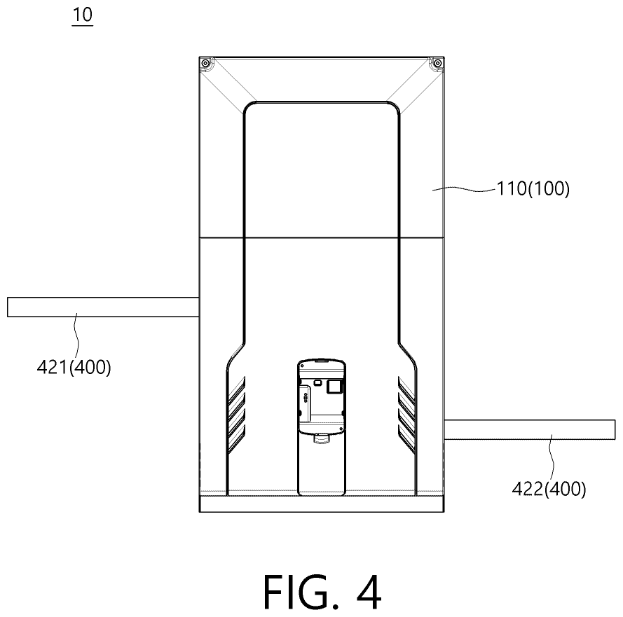

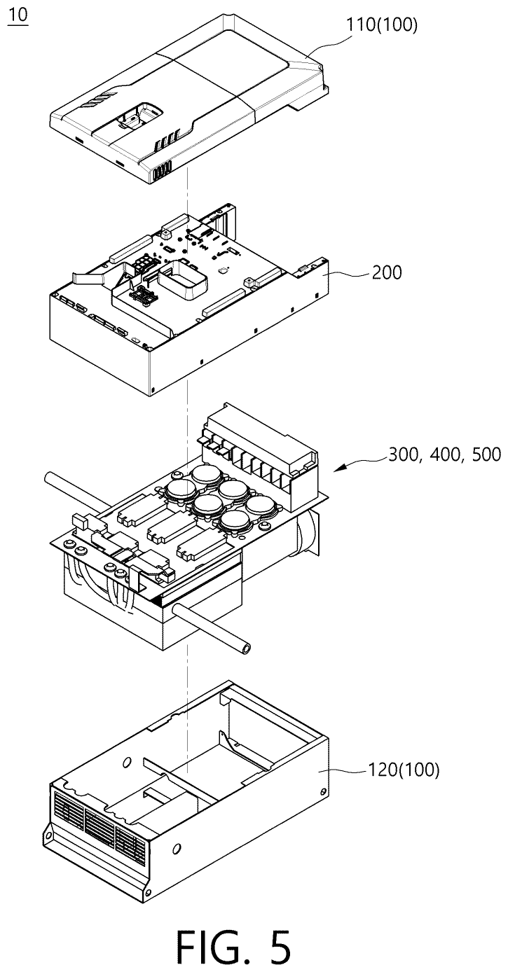

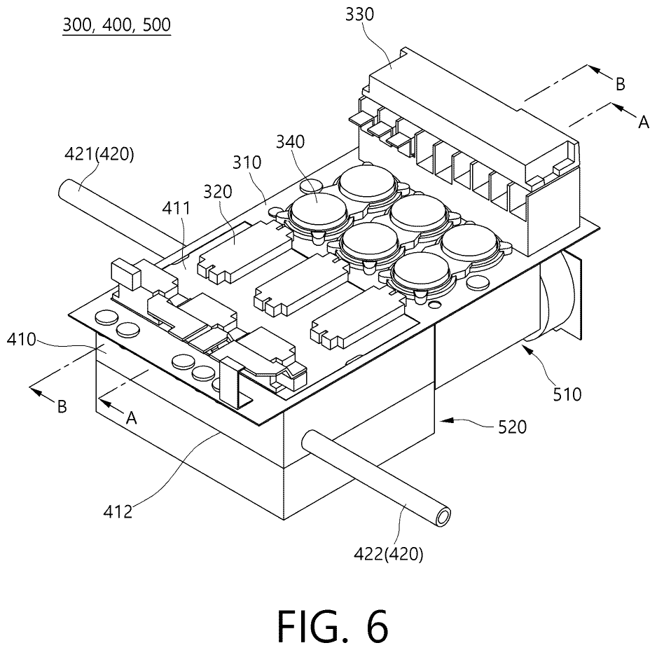

Referring to FIGS. 1 to 5, an inverter device 10 according to an embodiment of the present disclosure is illustrated. The inverter device 10 may be electrically connected to an external power source (not illustrated) and an external load (not illustrated), respectively.

The inverter device 10 may receive a current from the external power source (not illustrated), convert the current, and deliver the converted current to the load (not illustrated). In an embodiment, the inverter device 10 may be configured to primarily convert an alternating current into a direct current and then secondarily convert the direct current into an alternating current, thereby delivering it to the load (not illustrated). To this end, the inverter device 10 includes a power conversion module 300, which will be described below.

In addition, the inverter device 10 according to an embodiment of the present disclosure includes a configuration, that is, a cover 500 to be described below, that at least partially surrounds the power conversion module 300 that generates heat. This configuration may be in direct contact with the cooling module 400 to receive the generated heat by conduction. Accordingly, the cooling efficiency of the power conversion module 300 may be improved.

Since the operating principle of the inverter device 10 is a well-known technique, a detailed description thereof will be omitted.

In the illustrated embodiment, the inverter device 10 includes a frame 100, a housing 200, a power conversion module 300, a cooling module 400, and a cover 500.

The frame 100 forms a part of the outer shape of the inverter device 10. Other configurations of the inverter device 10 may be coupled to the frame 100 or accommodated inside the frame 100.

The frame 100 is coupled to the housing 200. The frame 100 is coupled to each side in the height direction of the housing 200, that is, to the upper and lower sides in the illustrated embodiment, respectively.

A space is formed inside the frame 100. The space accommodates other configurations of the inverter device 10, that is, the cooling module 400 and the cover 500.

The frame 100 may be configured to correspond to the shape of the inverter device 10. In the illustrated embodiment, the frame 100 has a polygonal column shape having a length in the front-rear direction greater than a width in the left-right direction and a height in the up-down direction.

The frame 100 may be composed of a plurality of parts. The plurality of parts may be disposed at different positions to be coupled to the housing 200 or to accommodate other configurations of the inverter device 10.

In the illustrated embodiment, the frame 100 includes a first frame 110 and a second frame 120.

The first frame 110 constitutes a part of the plurality of parts. In the illustrated embodiment, the first frame 110 is coupled to an upper side of the housing 200 in the height direction. The first frame 110 covers the housing 200 and the power conversion module 300 accommodated in the housing 200, and is coupled to the housing 200.

The first frame 110 is disposed to face the second frame 120 with the housing 200 and the power conversion module 300 accommodated in the housing 200 interposed therebetween.

The second frame 120 constitutes the remainder of the plurality of parts. The second frame 120 is coupled to the other side of the housing 200 in the height direction, that is, a lower side in the illustrated embodiment. The second frame 120 covers the housing 200 from the lower side and is coupled to the housing 200. The second frame 120 is disposed to face the first frame 110 with the housing 200 interposed therebetween.

A space is formed inside the second frame 120. The cooling module 400 and the cover 500 are positioned in the space of the second frame 120. As will be described below, the cooling module 400 may be positioned at both the inside and the outside of the second frame 120, respectively.

The space of the second frame 120 communicates with the outside. The cooling module 400 located in the space of the second frame 120 is in communication with an external fluid source, such as a water source. A fluid, such as water, delivered from the water source may flow into the inside of the second frame 120 along the cooling module 400, be heat-exchanged with the cooling module 400, and then be discharged to the outside of the second frame 120.

Accordingly, the heat generated in the power conversion module 300 may be discharged to the outside of the inverter device 10 via the cooling module 400.

That is, the heat generated in the power conversion module 300 may be discharged to the outside of the inverter device 10 by the cooling module 400. As a result, the power conversion module 300 may dissipate heat, and the heat dissipation efficiency of both the power conversion module 300 and the entire inverter device 10 may be improved.

The housing 200 constitutes another part of the outer shape of the inverter device 10. Other configurations of the inverter device 10 may be coupled to the housing 200 or accommodated inside the housing 200.

The housing 200 is coupled to the frame 100. One side of the housing 200 in the height direction, that is, an upper side in the illustrated embodiment, is coupled to the first frame 110. The other side of the housing 200 in the height direction, that is, a lower side in the illustrated embodiment, is coupled to the second frame 120.

A space is formed inside the housing 200. The power conversion module 300 is positioned in the space of the housing 200. The space of the housing 200 communicates with a space formed inside the second frame 120.

The housing 200 may be configured to correspond to the shape of the inverter device 10. In the illustrated embodiment, the housing 200 has a polygonal column shape having a length in the front-rear direction greater than a width in the left-right direction and a height in the up-down direction.

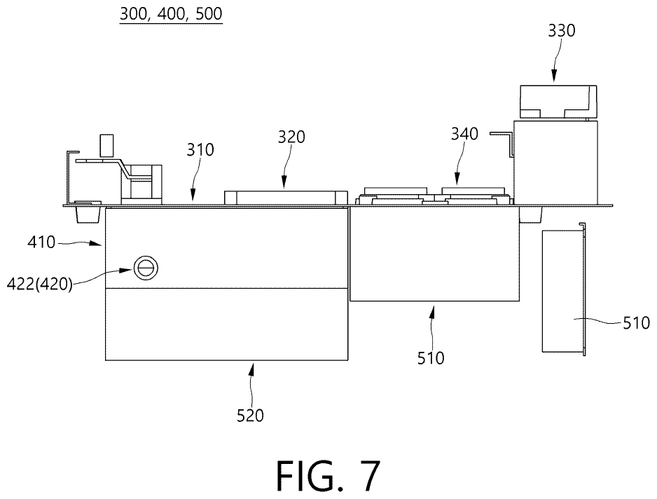

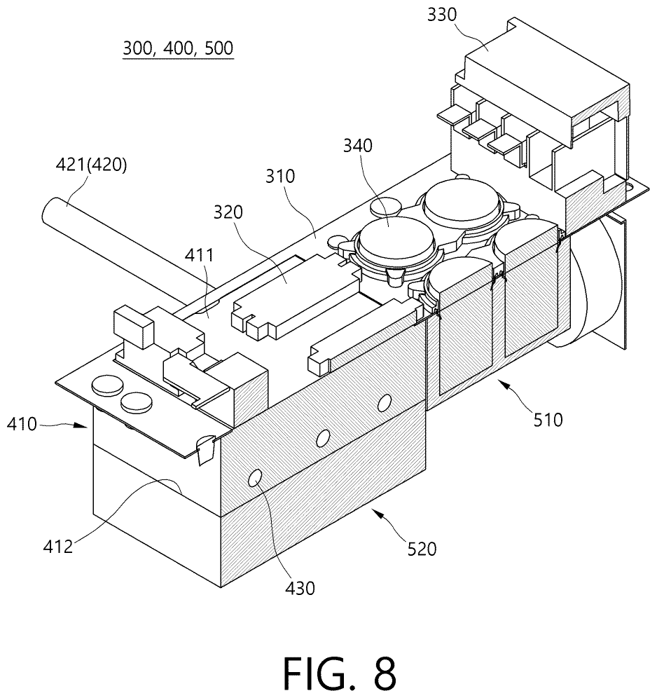

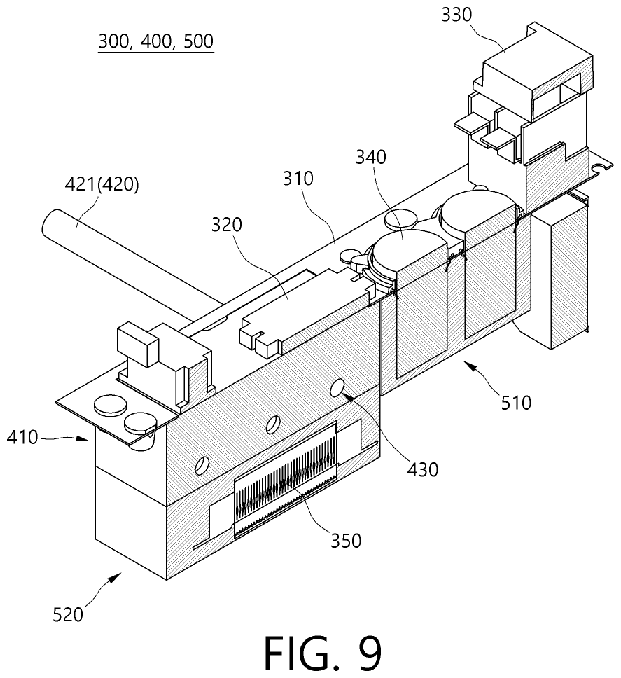

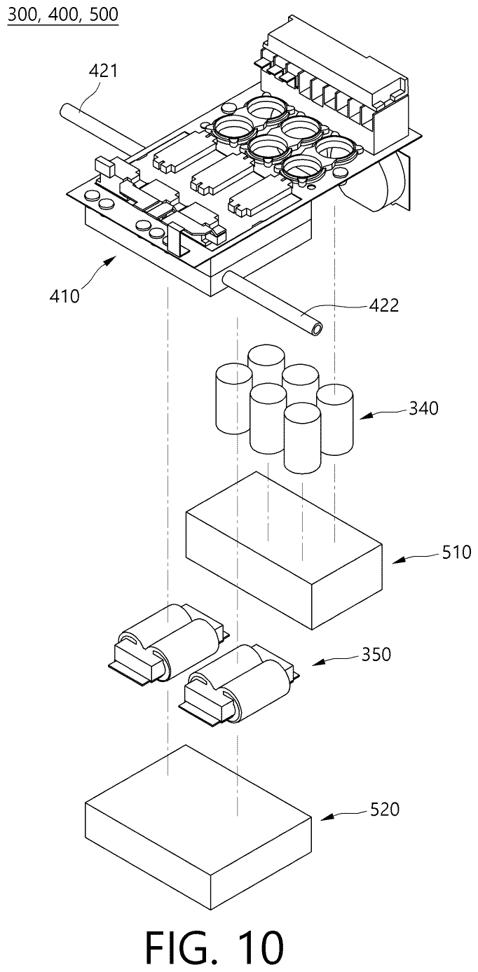

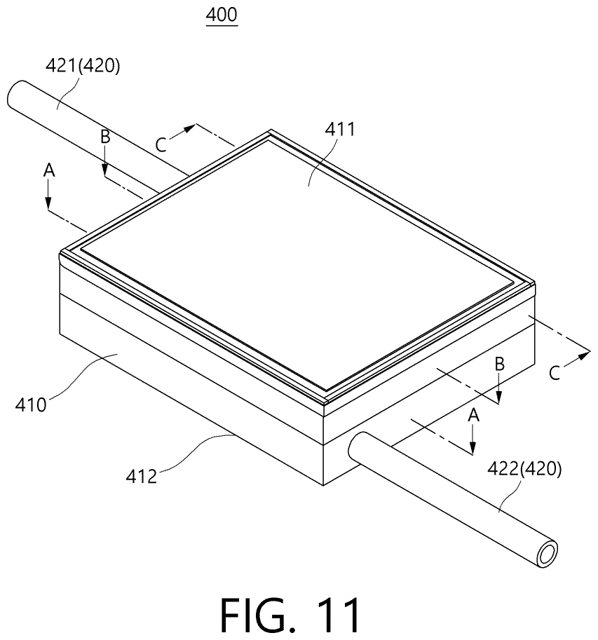

Referring to FIGS. 6 to 10, the inverter device 10 according to the illustrated embodiment includes a power conversion module 300.

The power conversion module 300 substantially serves to convert the received direct current into an alternating current. The alternating current converted by the power conversion module 300 may be delivered to an external load. The power conversion module 300 may be electrically connected to an external power source and the external load, respectively.

The power conversion module 300 is coupled to the frame 100 and the housing 200. Some configurations of the power conversion module 300 are accommodated in a space formed in the frame 100, specifically in the second frame 120. Other configurations of the power conversion module 300 are accommodated in a space formed inside the housing 200.

The power conversion module 300 is coupled to the cooling module 400. The heat generated in the power conversion module 300 may be transferred to the cooling module 400.

As will be described below, the heat exchange may be performed via the cooling module 400. Accordingly, it will be understood that the heat generated in the power conversion module 300 may be transferred to the cooling module 400.

The power conversion module 300 is coupled to the cover 500. Some configurations of the power conversion module 300 may be surrounded by the cover 500. In this case, the heat generated in the corresponding configurations of the power conversion module 300 may be transferred to the cover 500. As will be described below, the cover 500 may be in contact with the cooling module 400 and may directly exchange heat with it.

Thus, a portion of the heat generated in the power conversion module 300 may be transferred directly to the cooling module 400, and another portion may be transferred to the cooling module 400 through the cover 500. Accordingly, the power conversion module 300 may be effectively cooled, and a detailed description thereof will be provided below.

In the illustrated embodiment, the power conversion module 300 includes a substrate 310, an IGBT 320, a connector 330, a capacitor 340, and a reactor 350.

The substrate 310 constitutes the body of the power conversion module 300. The substrate 310 is coupled to other configurations of the power conversion module 300, that is, the IGBT 320, the connector 330, and the capacitor 340, respectively. The substrate 310 is electrically connected to the IGBT 320, the connector 330, the capacitor 340, and the reactor 350.

In this case, a through-hole to which a capacitor 340 is coupled may be formed inside the substrate 310. In the illustrated embodiment, a plurality of through-holes are configured to be biased toward one side in the longitudinal direction of the substrate 310, that is, a rear side. The capacitors 340 may be coupled to each of the through-holes, with a portion positioned above the substrate 310 and the remaining portion positioned below the substrate 310.

In addition, the substrate 310 may be electrically connected to the reactor 350. The substrate 310 may be electrically connected to the reactor 350 accommodated in the reactor cover 520 via a wire or the like.

The substrate 310 is coupled to the frame 100 and the housing 200, respectively. In the illustrated embodiment, the substrate 310 is positioned between the housing 200 and the second frame 120 located its lower side, and is coupled to both the housing 200 and the second frame 120, respectively.

The substrate 310 is coupled to the cooling module 400. An opening penetrating the thickness direction of the substrate 310, that is, the vertical direction in the illustrated embodiment, is formed inside the substrate 310. The cooling module 400 may pass through the opening and be at least partially exposed to the inner space of the housing 200.

In this case, the IGBT 320 may be disposed to be in contact with a portion where the cooling module 400 is exposed. Accordingly, the heat generated by the IGBT 320 may be efficiently transferred to the cooling module 400.

The substrate 310 is coupled to the cover 500. Specifically, the substrate 310 is coupled to a capacitor cover 510 that accommodates the capacitor 340.

The substrate 310 may be provided in any form that is coupled to the frame 100 and the housing 200, and electrically connectable to the IGBT 320, the connector 330, the capacitor 340, and the reactor 350. In an embodiment, the substrate 310 may be provided in the form of a printed circuit board (PCB) or a printed board assembly (PBA). In the above embodiment, the substrate 310 may be provided in a plate shape having a width in the left-right direction shorter than a length in the front-rear direction and a thickness in the up-down direction.

The IGBT 320 substantially serves to reconvert the primarily converted direct current into alternating current. The IGBT 320 may be electrically connected to an external power source and an external load, respectively.

The IGBT 320 may be provided in any form capable of converting the direct current into the alternating current. In an embodiment, the IGBT 320 may be provided in the form of a switching element.

A plurality of IGBTs 320 may be provided. The plurality of IGBTs 320 may be spaced apart from each other and may be coupled to the substrate 310 to be electrically connected. In the illustrated embodiment, three IGBTs 320 are provided and are spaced apart from each other in the width direction of the substrate 310, that is, the left-right direction.

In an embodiment, the IGBT 320 may be disposed to at least partially contact the cooling module 400. In the above embodiment, heat generated from the IGBT 320 may be transferred to the cooling module 400 by conduction. Accordingly, the IGBT 320 may be cooled to prevent damage caused by overheating.

The connector 330 electrically connects the power conversion module 300 to an external power source and an external load. The connector 330 is coupled to the substrate 310 to be electrically connected to it. Accordingly, the connector 330 may be electrically connected to the IGBT 320.

The connector 330 may be positioned to be biased toward one end of the substrate 310 in the longitudinal direction. In the illustrated embodiment, the connector 330 is positioned adjacent to a rear end of the substrate 310. The connector 330 may be disposed at any position capable of being electrically connected to the external power source and the external load.

A capacitor 340 is positioned between the IGBT 320 and the connector 330.

The capacitor 340 maintains voltage when the power delivered by the IGBT 320 is converted, thereby enabling a constant-voltage power supply. The capacitor 340 may be provided in the form of an element capable of storing power.

The capacitor 340 is electrically connected to other configurations of the power conversion module 300. In the illustrated embodiment, the capacitor 340 is electrically connected to the substrate 310, the IGBT 320, the connector 330, and the reactor 350.

The capacitor 340 is coupled to the substrate 310. One portion of the capacitor 340 in the height direction, that is, an upper portion in the illustrated embodiment, is coupled to and supported by the through-hole formed in the substrate 310.

The capacitor 340 is coupled to the capacitor cover 510. Another portion of the capacitor 340 in the height direction, that is, a lower portion in the illustrated embodiment, is coupled to the capacitor cover 510. In the above embodiment, the another portion of the capacitor 340 is not exposed to the inner space of the second frame 120.

In this case, heat generated from the capacitor 340 may be transferred to the capacitor cover 510 surrounding the capacitor 340. As will be described below, since the capacitor cover 510 is in contact with the cooling module 400, the heat may be discharged to the cooling module 400, thereby cooling the capacitor 340.

A plurality of capacitors 340 may be provided. The plurality of capacitors 340 may be spaced apart from each other and may be coupled to the substrate 310 and the capacitor cover 510, respectively. The plurality of capacitors 340 may be electrically connected to each other to increase the overall capacity of the capacitors 340.

In the illustrated embodiment, a total of six capacitors 340 are provided and are spaced apart from each other in both the longitudinal direction and the width direction of the substrate 310, that is, the front-rear direction and the left-right direction. In this case, the plurality of capacitors 340, although spaced apart from each other, are each coupled to the capacitor cover 510 but are not in direct contact with one another.

Therefore, heat generated from each capacitor 340 may be discharged to the outside through the capacitor cover 510, but may not be directly transferred to the other capacitors 340.

A detailed description of the process in which heat generated from the capacitor 340 is discharged along various paths to cool the capacitor 340 will be provided below.

The reactor 350 is configured to suppress harmonics of the power delivered to the inverter device 10 or the power converted by the inverter device 10, and to improve the power factor. The reactor 350 is electrically connected to the IGBT 320, the connector 330, and the capacitor 340 through the substrate 310.

The reactor 350 is coupled to the cover 500. Specifically, the reactor 350 is accommodated in the reactor cover 520 and disposed to be surrounded by the reactor cover 520. Accordingly, the reactor 350 may be disposed so as not to be directly exposed to the inner space of the second frame 120.

The reactor 350 may exchange heat with the reactor cover 520. Heat generated from the reactor 350 may be transferred to the reactor cover 520. As will be described below, the heat transferred to the reactor cover 520 may in turn be transferred to the cooling module 400.

Thus, the reactor 350 may be effectively cooled.

A plurality of reactors 350 may be provided. The plurality of reactors 350 may be spaced apart from each other and may each be electrically connected to the substrate 310. In addition, each of the reactors 350 may be accommodated in the reactor cover 520 to transfer the generated heat to the reactor cover 520. That is, heat exchange between the reactors 350 may be minimized.

In the illustrated embodiment, a pair of reactors 350 are provided and spaced apart from each other in the width direction of the substrate 310, that is, the left-right direction.

Since the operation of the reactor 350 is well known in the art, a detailed description thereof will be omitted.

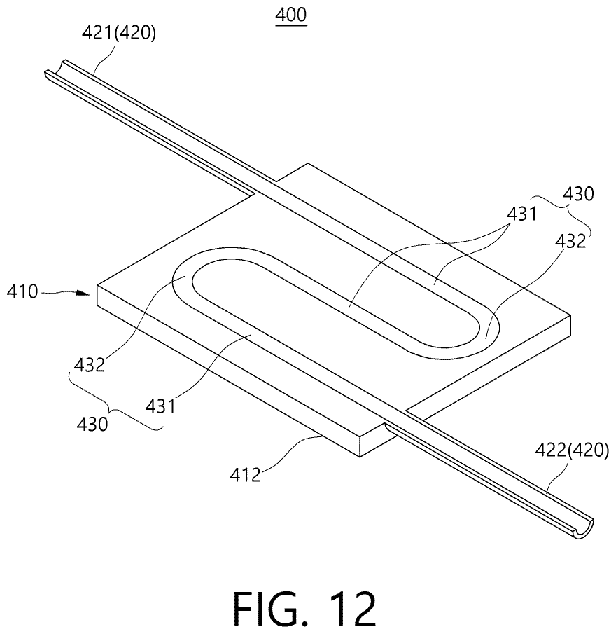

Referring again to FIGS. 6 to 14, the inverter device 10 according to an embodiment of the present disclosure includes a cooling module 400.

The cooling module 400 is coupled directly or indirectly to the IGBT 320 and the capacitor 340, respectively. Heat generated from the IGBT 320 or the capacitor 340 may be transferred to the cooling module 400. That is, the cooling module 400 may be configured to cool the IGBT 320 and the capacitor 340, respectively.

In an embodiment, the cooling module 400 may be configured to utilize fluids of different phases as a cooling medium. For example, water in a liquid phase may flow through the cooling module 400. In the above embodiment, the cooling module 400 may cool the power conversion module 300 in the form of water cooling.

Alternatively, the inverter device 10 according to an embodiment of the present disclosure may be configured to cool the power conversion module 300 by using only one of a liquid-phase cooling medium and a gas-phase cooling medium. In the above embodiment, the inverter device 10 may be configured to cool the power conversion module 300 by water cooling or air cooling.

The cooling module 400 is coupled to the power conversion module 300 and receives heat generated from the power conversion module 300. The cooling module 400 is configured to cool the received heat. That is, the cooling module 400 may be configured to directly exchange heat with the power conversion module 300.

The cooling module 400 is coupled to the frame 100. Specifically, the cooling module 400 is accommodated in a space formed inside the second frame 120. Some configurations of the cooling module 400 are coupled through a surface of the second frame 120.

The cooling module 400 communicates with the outside of the inverter device 10. Specifically, some configurations of the cooling module 400 penetrate through the surface of the second frame 120 and are exposed to the outside. These configurations may be fluidly connected to an external fluid source and an external fluid discharge, respectively.

The fluid introduced into the cooling module 400 from the external fluid source may absorb heat transferred to the cooling module 400 and then flow out to the external fluid discharge.

The cooling module 400 may be formed of a material having high thermal conductivity. In an embodiment, the cooling module 400 may be formed of copper, aluminum, or an alloy material containing either or both thereof.

The cooling module 400 may be disposed at any position to receive heat generated from the power conversion module 300, while being coupled to the power conversion module 300. In the illustrated embodiment, the cooling module 400 is positioned to be biased toward a front side corresponding to the position of the IGBT 320 of the power conversion module 300. The position of the cooling module 400 may vary depending on the position of the IGBT 320.

The cooling module 400 may be coupled to configurations of the power conversion module 300 to receive generated heat in the form of conduction. In the illustrated embodiment, the cooling module 400 is directly coupled to the IGBT 320.

In addition, the cooling module 400 may be coupled to configurations of the power conversion module 300 through the cover 500 to receive generated heat in the form of conduction. In the illustrated embodiment, the cooling module 400 is respectively coupled to the capacitor 340 and the reactor 350 by the capacitor cover 510 and the reactor cover 520.

In the illustrated embodiment, the cooling module 400 includes a cooling body 410, a cooling communicator 420, and a first cooling channel 430.

The cooling body 410 forms a part of the outer shape of the cooling module 400. The cooling body 410 corresponds to a portion of the cooling module 400 that is coupled to the power conversion module 300.

The cooling body 410 may be in contact with the IGBT 320 of the power conversion module 300 to exchange heat. The cooling body 410 may also be in contact with the capacitor cover 510 to receive heat generated from the capacitor 340. Furthermore, the cooling body 410 may be coupled to the reactor cover 520 to receive heat generated from the reactor 350.

In the illustrated embodiment, an upper side of the cooling body 410 is coupled to the IGBT 320, and a lower side of the cooling body 410 is coupled to the reactor 350. Furthermore, a rear side of the cooling body 410 is coupled to the capacitor cover 510.

In addition, the cooling body 410 may be disposed to be spaced apart from the second frame 120. Accordingly, unintended heat exchange between the cooling body 410 and the second frame 120 may be prevented.

The cooling body 410 may have a shape corresponding to that of an opening formed in the power conversion module 300, particularly in the substrate 310. In addition, the cooling body 410 may have a shape corresponding to that of the capacitor cover 510 and the reactor cover 520. In the illustrated embodiment, the cooling body 410 has a polygonal column shape, and has a length in the front-rear direction, a width in the left-right direction, and a height in the up-down direction.

In the illustrated embodiment, the cooling body 410 includes a first cooling surface 411 and a second cooling surface 412.

The first cooling surface 411 forms one outer surface of the cooling body 410. In the illustrated embodiment, the first cooling surface 411 forms an upper surface of the cooling body 410.

The first cooling surface 411 is coupled to the IGBT 320. The first cooling surface 411 may receive heat generated from the IGBT 320 in the form of conduction. In the illustrated embodiment, the first cooling surface 411 is coupled to and in contact with a lower surface of the IGBT 320.

The first cooling surface 411 is disposed to face the second cooling surface 412 with the first cooling channel 430 interposed therebetween. In the illustrated embodiment, the first cooling surface 411 is disposed to face the second cooling surface 412 along the height direction, that is, the up-down direction, of the cooling body 410.

The second cooling surface 412 forms another outer surface of the cooling body 410. In the illustrated embodiment, the second cooling surface 412 forms a lower surface of the cooling body 410.

The second cooling surface 412 is disposed to be spaced apart from the second frame 120. In the illustrated embodiment, the second cooling surface 412 is disposed to be spaced apart from a lower inner surface of the second frame 120.

In addition, unintended heat exchange between the cooling module 400 and the second frame 120 may be prevented by the above-described spacing.

The second cooling surface 412 is coupled to the reactor cover 520. Heat generated from the reactor 350 may be transferred to a cooling medium flowing through the first cooling channel 430 via the reactor cover 520 and the second cooling surface 412.

The second cooling surface 412 may have a shape corresponding to that of the first cooling surface 411. In the illustrated embodiment, the second cooling surface 412 is formed in a polygonal plate shape having a width in the left-right direction, a length in the front-rear direction, and a thickness in the up-down direction. It will be understood that the shape of the second cooling surface 412 may also correspond to that of the reactor cover 520.

The cooling communicator 420 fluidly connects the cooling module 400 to an external fluid source and an external fluid discharge. The cooling communicator 420 forms an inflow path and an outflow path for a cooling medium flowing through the cooling module 400.

The cooling communicator 420 is coupled to the second frame 120. In the illustrated embodiment, the cooling communicator 420 is coupled through a side surface in the width direction of the second frame 120, that is, a left side or a right side. An end of the cooling communicator 420 in the extending direction is exposed to the outside of the second frame 120 and is fluidly connected to the external fluid source and the external fluid discharge, respectively.

The cooling communicator 420 is coupled to the cooling body 410. The cooling communicator 420 extends from the cooling body 410 in a direction toward the outside of the second frame 120. In the illustrated embodiment, the cooling communicator 420 is coupled to a side surface in the width direction of the cooling body 410, that is, a left side or a right side, respectively.

The cooling communicator 420 is fluidly connected to the first cooling channel 430. Fluid introduced from the external fluid source into the cooling communicator 420 may flow into the first cooling channel 430. The fluid that flows along the first cooling channel 430 and is heat-exchanged with the cooling body 410 may exit to the external fluid discharge through the cooling communicator 420.

The cooling communicator 420 may have an any shape capable of fluidly connecting the external fluid source or the external fluid discharge with the first cooling channel 430. In the illustrated embodiment, the cooling communicator 420 has a circular cross-section, extends in the width direction of the cooling body 410, that is, the left-right direction, and is formed in a pipe shape with a hollow formed therethrough.

A plurality of cooling communicators 420 may be provided. One of the cooling communicators 420 may be connected to an external fluid source and may form an inflow path for the fluid. Another one of the cooling communicators 420 may be connected to an external fluid discharge and may form an outflow path for the fluid.

In the illustrated embodiment, a pair of cooling communicators 420 is provided, including a first communicator 421 and a second communicator 422.

The first communicator 421 is coupled to a left surface of the cooling body 410 and is coupled through a left surface of the second frame 120. The first communicator 421 communicates with a left end of the first cooling channel 430. A left end of the first communicator 421 is exposed to the outside of the second frame 120 and communicates with either an external fluid source or an external fluid discharge.

The second communicator 422 is coupled to a right surface of the cooling body 410 and is coupled through a right surface of the second frame 120. The second communicator 422 communicates with a right end of the first cooling channel 430. A right end of the second communicator 422 is exposed to the outside of the second frame 120 and communicates with the other of the external fluid source and the external fluid discharge.

The first cooling channel 430 defines a flow path along which a fluid introduced into the cooling module 400 flows while being heat-exchanged with the cooling module 400. The first cooling channel 430 is formed inside the cooling body 410.

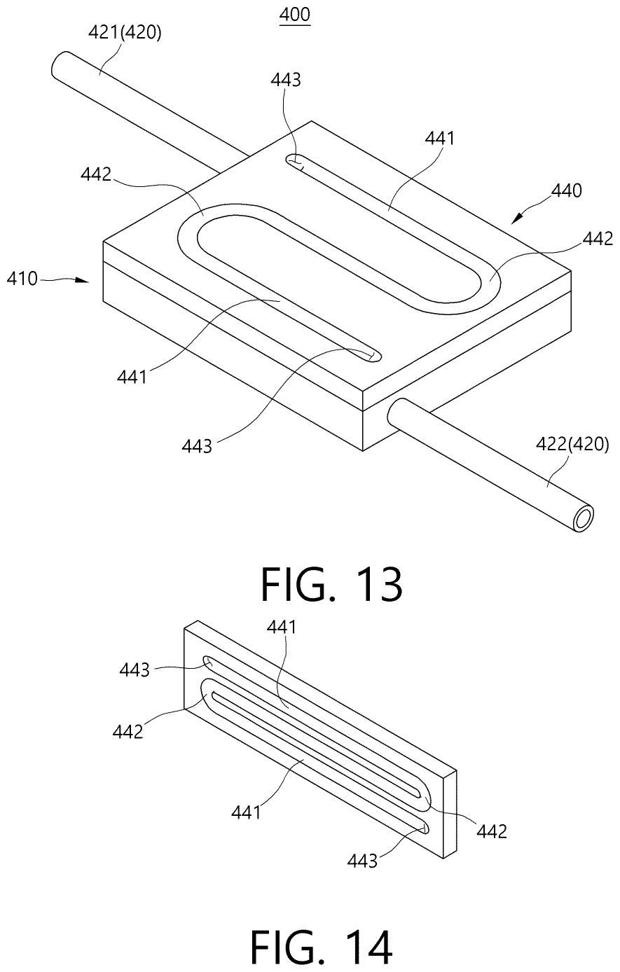

That is, as best illustrated in FIG. 12, the first cooling channel 430 is formed as a recessed groove inside the cooling body 410. Each end of the first cooling channel 430 is open and fluidly communicates with a respective cooling communicator 420.

In the illustrated embodiment, the left end of the first cooling channel 430 communicates with the first communicator 421. In addition, the right end of the first cooling channel 430 communicates with the second communicator 422.

The first cooling channel 430 may be formed in any shape that is fluidly connectable to the cooling communicator 420 and in which fluid may flow within the cooling body 410. In the illustrated embodiment, the first cooling channel 430 is formed in an S-shaped pattern including three first straight channel sections 431 and two first curved channel sections 432.

In this case, the first cooling channel 430 is preferably extended to a length sufficient for the fluid flowing therein to be adequately heat-exchanged with the cooling body 410, while not being so long as to cause an excessive reduction in the flow rate of the fluid.

Referring to FIG. 13, a modified example of the cooling module 400 according to an embodiment of the present disclosure is illustrated.

The cooling module 400 according to the illustrated embodiment includes a plurality of cooling channels formed to be stacked along a height direction, that is, an up-down direction. That is, the first cooling channel 430 described above is positioned in a lower portion of the interior of the cooling body 410, and the second cooling channel 440 is positioned in an upper portion of the interior of the cooling body 410.

In this case, the first cooling channel 430 and the second cooling channel 440 are in communication with each other. Accordingly, a portion of the cooling medium introduced into the first cooling channel 430 through the cooling communicator 420 may be delivered to the second cooling channel 440. In addition, the portion of the cooling medium that has flowed through the second cooling channel 440 may flow again through the first cooling channel 430 and be discharged to the outside through the cooling communicator 420.

In another embodiment, the cooling medium introduced through the cooling communicator 420 may be configured to flow only through the second cooling channel 440 and then be discharged.

The second cooling channel 440 is positioned adjacent to the power conversion module 300, specifically to the IGBT 320, compared to the first cooling channel 430. Accordingly, it will be understood that the cooling medium flowing through the second cooling channel 440 may more effectively receive heat from the IGBT 320.

The second cooling channel 440 may have any shape that allows the cooling medium to flow and receive heat generated from the power conversion module 300. In the illustrated embodiment, the second cooling channel 440 is formed in an S-shaped pattern similar to the first cooling channel 430.

In the illustrated embodiment, the second cooling channel 440 includes a second straight channel section 441, a second curved channel section 442, and a channel communication hole 443.

The second straight channel section 441 extends in a width direction of the cooling body 410, that is, in a left-right direction in the illustrated embodiment. A plurality of second straight channel sections 441 may be provided and may be spaced apart from each other in a longitudinal direction of the cooling body 410, that is, in a front-rear direction in the illustrated embodiment.

Some of the plurality of second straight channel sections 441 may be in communication with the first cooling channel 430 through the channel communication hole 443. In the illustrated embodiment, the rearmost second straight channel section 441 is in communication with the first cooling channel 430 via the channel communication hole 443 positioned on a left side. In addition, the frontmost second straight channel section 441 is in communication with the first cooling channel 430 via the channel communication hole 443 positioned on a right side.

The plurality of second straight channel sections 441 are in communication with each other by the plurality of second curved channel sections 442. Each second curved channel section 442 extends between ends of adjacent second straight channel sections 441. The second curved channel sections 442 may be formed in a rounded shape to be convex toward an outer side in a width direction of the cooling body 410.

A plurality of second curved channel sections 442 may be provided. The plurality of second curved channel sections 442 may be configured to communicate with the plurality of second straight channel sections 441 at respective different positions.

In the illustrated embodiment, a pair of second curved channel sections 442 is provided. One of the second curved channel sections 442 is configured to connect a second straight channel section 441 positioned at a frontmost side with another second straight channel section 441 positioned at a central side. The other second curved channel section 442 is configured to connect the second straight channel section 441 positioned at the central side with another second straight channel section 441 positioned at a rearmost side.

The channel communication hole 443 fluidly connects the first cooling channel 430 and the second cooling channel 440. In an embodiment, the channel communication hole 443 may be configured to connect the first straight channel section 431 and the second straight channel section 441.

The channel communication hole 443 may have any shape capable of fluidly connecting the first cooling channel 430 and the second cooling channel 440. In an embodiment, the channel communication hole 443 penetrates in a height direction of the cooling body 410, that is, in a vertical direction in the illustrated embodiment, and one end in the extending direction of the hole may be connected to the first cooling channel 430, and the other end may be connected to either the second straight channel section 441 or the second curved channel section 442.

A plurality of channel communication holes 443 may be provided. The plurality of channel communication holes 443 may fluidly connect the first cooling channel 430 and the second cooling channel 440 at different positions. Each channel communication hole 443 may be connected to an end of the second straight channel section 441 other than the end connected to the second curved channel section 442.

In the illustrated embodiment, a pair of channel communication holes 443 is provided. One of the channel communication holes 443 is located at a left end of the second straight channel section 441 positioned on a rear side. The one channel communication hole 443 constitutes either an inflow path or an outflow path of the cooling medium to the second cooling channel 440.

Further, the other channel communication hole 443 is located at a right end of the second straight channel section 441 positioned on a front side. The other channel communication hole 443 constitutes the other one of the inflow path and the outflow path of the cooling medium to the second cooling channel 440.

Referring to FIG. 14, a cooling module 400 according to another embodiment of the present disclosure is illustrated. In this embodiment, the cooling module 400 includes a second cooling channel 440 configured to communicate with the first cooling channel 430.

In this case, the second cooling channel 440 is positioned to be biased toward one side in a longitudinal direction of the cooling body 410, that is, toward a rear side in the illustrated embodiment. That is, in the above embodiment, the second cooling channel 440 is positioned adjacent to the capacitor cover 510 to effectively receive heat generated from the capacitor 340.

In the above embodiment, the second cooling channel 440 may be configured in any shape capable of communicating with the first cooling channel 430 to form a fluid flow path. In the illustrated embodiment, the second cooling channel 440 includes a second straight channel section 441, a second curved channel section 442, and a channel communication hole 443.

In the illustrated embodiment, a plurality of second straight channel sections 441 are provided and arranged side by side while being spaced apart from each other in a height direction, that is, a vertical direction, of the cooling body 410. A plurality of second curved channel sections 442 are also provided to interconnect the plurality of second straight channel sections 441.

In this case, the second straight channel section 441 may communicate with the first cooling channel 430 and the cooling communicator 420 via the channel communication hole 443. In the above embodiment, the channel communication hole 443 may be formed as a space extending in a longitudinal direction, that is, a front-rear direction, of the cooling body 410. One end of the channel communication hole 443 in the extending direction may communicate with the second straight channel section 441 or the second curved channel section 442, and the other end may communicate with the first cooling channel 430 or the cooling communicator 420.

Referring again to FIGS. 6 to 10, the inverter device 10 according to an embodiment of the present disclosure includes a cover 500.

The cover 500 is formed to surround a portion of the configurations of the power conversion module 300. A space is formed inside the cover 500 to accommodate the portion of the configurations of the power conversion module 300.

The space may be formed in a shape corresponding to the portion of the configurations of the power conversion module 300. In the above embodiment, heat generated from the portion of the configurations of the power conversion module 300 may be transferred to the cover 500.

The cover 500 is accommodated in an inner space of the second frame 120 and is coupled to the cooling module 400. Specifically, a part of the cover 500 is coupled to one side of the cooling body 410 in a longitudinal direction, that is, a rear side, to exchange heat. Another part of the cover 500 is coupled to the second cooling surface 412 provided in the cooling body 410 to exchange heat.

The cover 500 may be formed of a material having high thermal conductivity. In an embodiment, the cover 500 may be formed of copper, aluminum, or an alloy material including either or both thereof.

A plurality of covers 500 may be provided. The plurality of covers 500 may respectively accommodate different configurations included in the power conversion module 300 and may exchange heat with the accommodated configurations. In addition, the plurality of covers 500 may be coupled to the cooling module 400 at different positions to exchange heat therewith.

In the illustrated embodiment, the cover 500 includes a capacitor cover 510 and a reactor cover 520.

The capacitor cover 510 is configured to accommodate the capacitor 340 and to exchange heat therewith. The capacitor cover 510 is configured to receive heat generated from the capacitor 340.

A space configured to accommodate the capacitor 340 may be formed inside the capacitor cover 510. The space may be formed in a shape corresponding to that of the capacitor 340. The capacitor 340 accommodated in the space may be in contact with an inner surface of the capacitor cover 510. Accordingly, heat generated from the capacitor 340 may be transferred to the capacitor cover 510 in the form of conduction.

The capacitor cover 510 is coupled to the substrate 310. One side of the capacitor cover 510 in a height direction, that is, an upper side in the illustrated embodiment, may be coupled to a lower side of the substrate 310.

The capacitor cover 510 is coupled to the cooling module 400. Specifically, the capacitor cover 510 is coupled to one side in a longitudinal direction of the cooling body 410, that is, a rear side in the illustrated embodiment. Heat generated from the capacitor 340 may be transferred to the cooling body 410 via the capacitor cover 510. It will be understood that the heat transferred to the cooling body 410 may in turn be transferred to the cooling medium flowing in the first cooling channel 430.

The capacitor cover 510 may at least partially accommodate the capacitor 340. In the illustrated embodiment, the capacitor cover 510 is configured to accommodate all but a portion adjacent to an upper end of the capacitor 340. The portion adjacent to the upper end of the capacitor 340 may be coupled to and supported by the substrate 310.

In an embodiment, the capacitor cover 510 may be coupled to the capacitor 340 and may be moved together therewith. In other words, the capacitor cover 510 and the capacitor 340 may be configured as a single module.

The capacitor cover 510 may have any shape capable of accommodating the capacitor 340, being coupled to the cooling module 400, and exchanging heat with each of them. In the illustrated embodiment, the capacitor cover 510 has a polygonal pillar shape having a rectangular cross-section and a height in the vertical direction.

In any case, it is sufficient if the capacitor cover 510 is reliably in contact with the cooling module 400, and the inner surface of the capacitor cover 510 is also reliably in contact with the accommodated capacitor 340 to allow heat exchange.

The reactor cover 520 is configured to accommodate the reactor 350. The reactor cover 520 may exchange heat with the reactor 350 and is configured to receive heat generated from the reactor 350.

A space for accommodating the reactor 350 may be formed inside the reactor cover 520. The space may have a shape corresponding to the shape of the reactor 350. The reactor 350 accommodated in the space may be in contact with an inner surface of the reactor cover 520. Accordingly, heat generated from the reactor 350 may be transferred to the reactor cover 520 in the form of conduction.

The reactor cover 520 is coupled to the cooling module 400. Specifically, the reactor cover 520 is coupled to the second cooling surface 412 at a lower side of the cooling body 410. The reactor cover 520 is positioned between a lower inner surface of the second frame 120 and the cooling body 410.

Heat generated from the reactor 350 may be transferred to the cooling body 410 via the reactor cover 520. It will be understood that the heat transferred to the cooling body 410 may be in turn transferred to a cooling medium flowing through the first cooling channel 430.

The reactor cover 520 may completely accommodate the reactor 350. That is, the reactor 350 may be configured not to be exposed to the outside of the reactor cover 520. In the above embodiment, the reactor cover 520 may be coupled to the reactor 350 and may be moved together therewith. In other words, the reactor cover 520 and the reactor 350 may be configured as a single module.

The reactor cover 520 may have any shape capable of accommodating the reactor 350, being coupled to the cooling module 400, and exchanging heat with each of them. In the illustrated embodiment, the reactor cover 520 has a polygonal pillar shape having a rectangular cross-section and a height in the vertical direction.

In this case, a surface of the reactor cover 520 that faces the second cooling surface 412, that is, an upper surface in the illustrated embodiment, may be formed to have a shape corresponding to the shape of the second cooling surface 412. In the above embodiment, the contact reliability between the reactor cover 520 and the second cooling surface 412 and the resulting heat-exchange efficiency may be improved.

In any case, it is sufficient if the reactor cover 520 and the cooling module 400 are reliably in contact with each other, and if the inner surface of the reactor cover 520 is also reliably in contact with the accommodated reactor 350 to allow heat exchange.

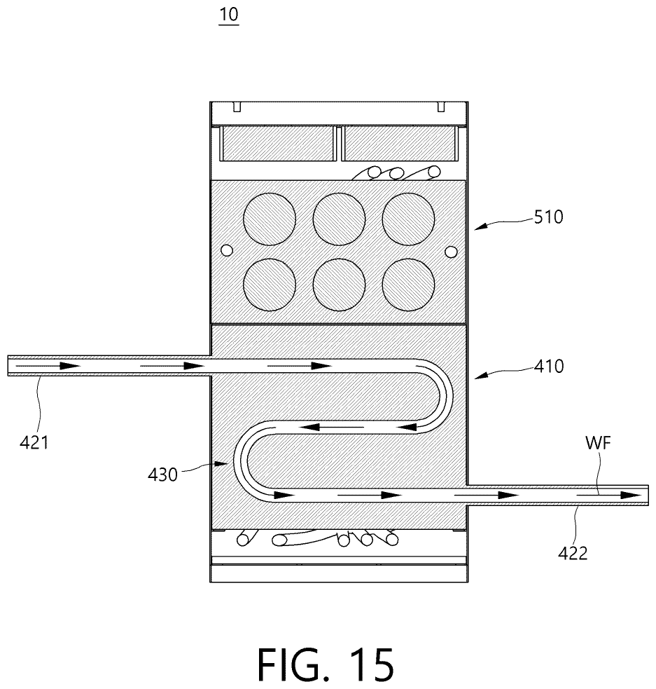

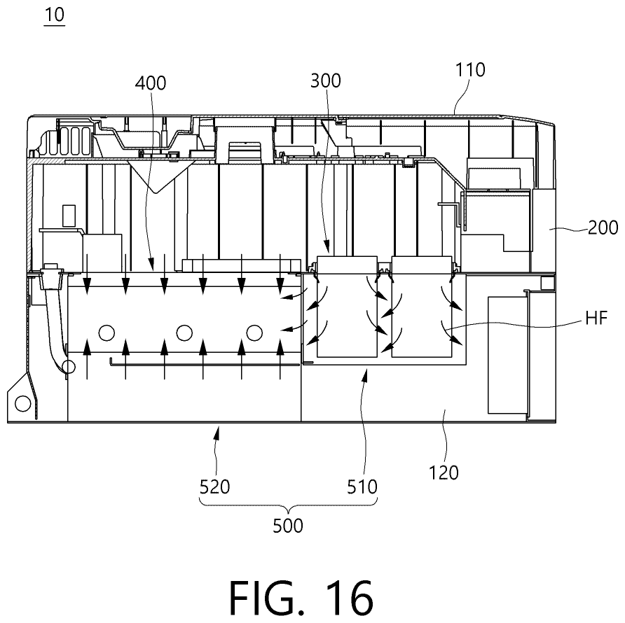

Referring to FIGS. 15 and 16, an example of a flow process of a cooling medium formed inside the inverter device 10 according to an embodiment of the present disclosure is illustrated.

As described above, in the inverter device 10 according to an embodiment of the present disclosure, main configurations that generate heat, that is, the IGBT 320, the capacitor 340, and the reactor 350, are disposed to be in contact with other configurations. Heat generated from the IGBT 320, the capacitor 340, and the reactor 350 may be transferred to other configurations in the form of conduction.

In addition, in an embodiment, heat generated from the IGBT 320, the capacitor 340, and the reactor 350 may be transferred to a plurality of cooling media configured in different phases.

Accordingly, the IGBT 320, the capacitor 340, and the reactor 350 may be effectively cooled.

In the following description, it is assumed that the cooling module 400 cools the power conversion module 300 by utilizing water. Alternatively, it will be understood that the cooling module 400 may utilize other liquid-phase fluids such as cooling oil.

Referring to FIG. 15, an embodiment in which the power conversion module 300 is cooled by water cooling is illustrated. In the illustrated embodiment, a water flow (WF) is formed from one side to the other side in the width direction of the inverter device 10. Hereinafter, it is assumed that the first communicator 421 on the left side defines an inflow path of water, and the second communicator 422 on the right side defines an outflow path of water.

Water introduced from an external fluid source enters the first cooling channel 430 through the first communicator 421. The water flow (WF) is guided to the first cooling channel 430 through a hollow formed inside the first communicator 421. The introduced water flows along the plurality of first straight channel sections 431 and first curved channel sections 432, exchanges heat with the cooling body 410, and then flows out to the outside through the second communicator 422.

Accordingly, the water introduced into the first cooling channel 430 may flow for a sufficiently long time and receive heat generated from the power conversion module 300.

At this time, the cooling medium flowing in the first cooling channel 430, that is, water, may receive heat from a plurality of configurations.

That is, water may receive heat from the IGBT 320 coupled to the first cooling surface 411, the reactor cover 520 coupled to the second cooling surface 412 and the reactor 350 accommodated therein, and the capacitor cover 510 coupled to the cooling body 410 and the capacitor 340 accommodated therein.

Consequently, the cooling efficiency of the power conversion module 300 and the inverter device 10 using water may be improved.

Referring to FIG. 16, a path along which heat generated from the inverter device 10 according to an embodiment of the present disclosure is transferred by the above-described process is illustrated as an example.

First, heat generated from the IGBT 320 is transferred to the cooling module 400 through the first cooling surface 411. The transferred heat is then delivered to the cooling medium flowing along the first cooling channel 430 and is discharged to the outside of the inverter device 10.

The IGBT 320 may be cooled by the above-described process.

In addition, heat generated from the capacitor 340 is transferred to the capacitor cover 510 that accommodates it. The transferred heat is then delivered to the cooling module 400 coupled to the capacitor cover 510. The heat is further transferred to the cooling medium flowing along the first cooling channel 430 and discharged to the outside of the inverter device 10.

The capacitor 340 may also be cooled by the above-described process.

Furthermore, heat generated from the reactor 350 is transferred to the reactor cover 520 that accommodates it. The transferred heat is then delivered to the cooling module 400 through the second cooling surface 412. The heat is further transferred to the cooling medium flowing along the first cooling channel 430 and discharged to the outside of the inverter device 10.

The reactor 350 may also be cooled by the above-described process.

The inverter device 10 according to the above-described embodiment of the present disclosure includes a cooling module 400 configured to be directly in contact with and coupled to a part of the configurations of the power conversion module 300. In addition, other configurations of the power conversion module 300 are accommodated in the cover 500, and the cover 500 is configured to be in contact with and coupled to the cooling module 400.

That is, heat generated from each configuration of the power conversion module 300 may be transferred to the cooling module 400 along various paths. Accordingly, heat generated from a plurality of heat sources may be effectively discharged to the outside of the inverter device 10.

Although exemplary embodiments of the present disclosure have been described, the idea of the present disclosure is not limited to the embodiments set forth herein. Those of ordinary skill in the art who understand the idea of the present disclosure may easily propose other embodiments through supplement, change, removal, addition, etc. of elements within the same idea, but the embodiments will be also within the scope of the present disclosure.

| | |
|---|---|
| 10: inverter device | 100: frame |
| 110: first frame | 120: second frame |
| 200: housing | 300: power conversion module |
| 310: substrate | 320: IGBT member |
| 330: connector | 340: capacitor |
| 350: reactor | 400: cooling module |
| 410: cooling body | 411: first cooling surface |
| 412: second cooling surface | 420: cooling communicator |
| 421: first communicator | 422: second communicator |
| 430: first cooling channel | 431: first straight channel section |
| 432: first curved channel section | 440: second cooling channel |
| 441: second straight channel section | 442: second curved channel section |
| 443: channel communication hole | 500: cover |
| 510: capacitor cover | 520: reactor cover |
| WF: water flow | HF: heat movement |

1. An inverter device comprising:
a power conversion module configured to convert one of a direct current (DC) power and an alternating current (AC) power into the other;
a cooling module configured to be coupled to the power conversion module and to receive heat generated therefrom; and
a cover configured to accommodate the power conversion module and to be coupled to the cooling module to exchange heat therewith,
wherein the cooling module is configured to be in direct contact with a part of configurations of the power conversion module to exchange heat therewith, and
wherein the cover is disposed to accommodate another part of the configurations of the power conversion module to receive heat generated therefrom and to be in direct contact with the cooling module.

2. The inverter device of claim 1, wherein the power conversion module includes:
a substrate configured to form an outer shape thereof and to be coupled to the cooling module and the cover; and
a capacitor configured to be coupled to and electrically connected with the substrate,
wherein the cover includes:
a capacitor cover configured to be coupled to the substrate, to at least partially accommodate the capacitor, and to be in contact with the cooling module.

3. The inverter device of claim 2, wherein the capacitor is coupled through the substrate,
wherein the capacitor extends in one direction, one portion in an extending direction of the capacitor is positioned at one side of the substrate, and another portion in the extending direction of the capacitor is positioned at the other side of the substrate, and
wherein the capacitor cover is positioned at the other side of the substrate to accommodate another portion of the capacitor.

4. The inverter device of claim 3, wherein a length of the one portion of the capacitor is configured to be shorter than a length of another portion of the capacitor.

5. The inverter device of claim 2, wherein the cooling module includes:
a cooling body configured to be coupled to the power conversion module and the cover, respectively, to receive heat generated from the power conversion module; and
a cooling channel configured to be disposed inside the cooling body and to be fluidly connected to an outside, and to allow a cooling medium receiving the heat to flow therethrough,
wherein the capacitor cover is coupled to one surface of the cooling body.

6. The inverter device of claim 5, wherein the cooling module includes:
a cooling communicator configured to be coupled to the cooling body, fluidly connected to the cooling channel, and partially exposed to the outside, and
wherein the capacitor cover is coupled to one of sides of the cooling body on which the cooling communicator is not provided.

7. The inverter device of claim 1, wherein the power conversion module includes:
a substrate configured to form an outer shape thereof and to be coupled to the cooling module and the cover; and
a reactor configured to be electrically connected to the substrate,
wherein the cover includes:
a reactor cover configured to be coupled to the cooling module and to accommodate the reactor.

8. The inverter device of claim 7, wherein the cooling module includes:
a cooling body configured to be coupled to the power conversion module and the cover, respectively, to receive heat generated from the power conversion module, and
wherein the reactor cover is disposed to face the substrate with the cooling body interposed therebetween.

9. The inverter device of claim 8, wherein the cooling body includes:
a first cooling surface configured to be coupled to the substrate; and
a second cooling surface configured to be spaced apart from the first cooling surface to face the first cooling surface, and to be coupled to the reactor cover.

10. The inverter device of claim 1, wherein the power conversion module includes:
a substrate configured to form an outer shape thereof and to be coupled to the cooling module and the cover, and to have an opening formed therethrough; and
an insulated gate bipolar transistor (IGBT) configured to be electrically connected to the substrate and to be disposed adjacent to the opening,
wherein the cooling module is disposed to be at least partially exposed through the opening and in contact with the IGBT.

11. The inverter device of claim 1, wherein the cooling module includes:
a cooling body configured to be coupled to the power conversion module and the cover, respectively, to receive heat generated from the power conversion module, and
a cooling channel configured to be disposed inside the cooling body and to be fluidly connected to an outside, and to allow a cooling medium receiving the heat to flow therethrough,
wherein the cooling channel includes:
a first cooling channel positioned to be biased toward one side in a height direction of the cooling body.

12. The inverter device of claim 11, wherein the cooling channel includes:
a second cooling channel positioned to be biased toward the other side in a height direction of the cooling body and configured to communicate with the first cooling channel,
wherein the cooling module includes:
a cooling communicator configured to communicate with either the first cooling channel or the second cooling channel and to form an inflow path and an outflow path of the cooling medium.

13. The inverter device of claim 11, wherein the power conversion module includes:
a substrate configured to form an outer shape thereof and to be coupled to the cooling module and the cover; and
a capacitor configured to be coupled to and electrically connected to the substrate,
wherein the cooling channel includes:
a second cooling channel positioned to be biased toward one side in a longitudinal direction of the cooling body to be adjacent to the capacitor and configured to communicate with the first cooling channel.
